(19) United States
(12) Patent Application Publication
(10) Pub. No.: US 2015/0102703 A1
(43) Pub. Date: Apr. 16, 2015

(54) VIBRATOR, OSCILLATOR, ELECTRONIC DEVICE, AND MOVING OBJECT

(71) Applicant: Seiko Epson Corporation, Tokyo (JP)

(72) Inventor: Akinori YAMADA, Ina (JP)

(21) Appl. No.: 14/512,661

(22) Filed: Oct. 13, 2014

(30) Foreign Application Priority Data
Oct. 15, 2013 (JP) 2013-214420

(51) Int. Cl. H02N 1/00; B81B 7/00

(52) U.S. Cl. CPC H02N 1/00; B81B 7/00
USPC 310/309

(57) ABSTRACT

A MEMS vibrator includes: a substrate; a supporting portion which is connected to the substrate; a base portion which is connected to the supporting portion; and a plurality of vibration portions which is separated from the substrate and extends in different directions from each other from the base portion, and in which the adjacent vibration portions vibrate in a phase of a reverse direction to each other. In the vibration portion, the base portion has a vibration node, and at least a part of the supporting portion is overlapped with the vibration node in a planar view.

### BACKGROUND

1. Technical Field

The present invention relates to a vibrator, an oscillator provided with the vibrator, an electronic device, and a moving object.

2. Related Art

An electro-mechanical system structure (for example, a vibrator, a filter, a sensor, or a motor) provided with a mechanically movable structure which is called a micro electro mechanical system (MEMS) device which is formed by using semiconductor micro fabrication technology, is generally known. Among these, compared to an oscillator and a resonator using quartz crystal or a dielectric in the related art, since a MEMS vibrator is easy to manufacture by incorporating a semiconductor circuit and advantageous in refinement and high functionality, the usage range thereof widens.

As representative examples of the MEMS vibrator in the related art, a comb type vibrator which vibrates in a direction parallel to a substrate surface provided with the vibrator, and a beam type vibrator which vibrates in a thickness direction of the substrate, are known. The beam type vibrator is a vibrator which has a fixed electrode formed on the substrate or a movable electrode separated and disposed on the substrate, and according to a method of supporting the movable electrode, a cantilevered beam type (clamped-free beam), a double-end supported beam type (clamped-clamped beam), or a both-ends free beam type (free-free beam) are known.

In the MEMS vibrator in a cantilevered beam type in JP-A-2012-85085, in a side surface portion of a first electrode provided on a main surface of the substrate, a corner of the side surface portion provided on a supporting portion side of a movable second electrode is formed substantially perpendicularly. For this reason, it is possible to reduce an effect of the variation of a vibration characteristic caused by a variation in an electrode shape, and to obtain a stable vibration characteristic.

However, the MEMS vibrator in JP-A-2012-85085 is advantageous in that the size thereof can be reduced since there is one supporting portion. However, since the mass of the supporting portion which fixes the cantilevered beam that vibrates in the thickness direction of the substrate is small, there is a problem in that a flexural vibration of the beam of the movable second electrode cannot be attenuated, the vibration of the beam is transmitted to the supporting portion and leaked to the entire substrate, a high Q value cannot be obtained, and a stable vibration characteristic or a desired vibration characteristic cannot be obtained.

### SUMMARY

An advantage of some aspects of the invention is to solve at least a part of the problems described above, and the invention can be implemented as the following forms or application examples.

### Application Example 1

This application example is directed to a vibrator including: a substrate; a supporting portion which is disposed on the substrate; a base portion which is disposed on the supporting portion and has a vibration node; and a vibration portion which extends from the base portion. In a planar view, at least a part of the supporting portion is overlapped with the vibration node.

According to this application example, a supporting portion is provided at apart which is the vibration node where a vibration displacement amount is extremely small or rarely exists, and supports an upper electrode configured to have the base portion and the vibration portion. For this reason, vibration generated by vibration of the vibration portion does not leak to the substrate, and it is possible to obtain a vibrator having a high Q value in which vibration leakage and deterioration of vibration efficiency are suppressed.

### Application Example 2

This application example is directed to the vibrator according to the application example described above, which further includes a fixed electrode, which faces the vibration portion and is disposed on the substrate.

According to this application example, by providing the fixed electrode at a position facing the vibration portion, when an AC voltage is applied between the vibration portion and the fixed electrode, vibration is likely to occur in which the vibration portion is attracted to or pulled away from the fixed electrode. For this reason, it is possible to obtain a vibrator having a stable vibration characteristic.

### Application Example 3

This application example is directed to the vibrator according to the application example described above, which further includes a movable electrode having the vibration portion.

According to this application example, as the AC voltage is applied between the movable electrode and the fixed electrode provided on the substrate, it is possible to obtain a vibrator having a stable vibration characteristic.

### Application Example 4

This application example is directed to the vibrator according to the application example described above, wherein the vibration portion vibrates in a direction that intersects a plane surface which includes the fixed electrode.

According to this application example, when the AC voltage is applied between the movable electrode and the fixed electrode, the vibration portion of the movable electrode is attracted to or pulled away from the fixed electrode. In other words, it is possible to allow flexural vibration which has displacement in a direction that intersects the plane surface which includes the fixed electrode to be performed, and to obtain a vibrator having a stable vibration characteristic.

### Application Example 5

This application example is directed to the vibrator according to the application example described above, wherein at least a part of the supporting portion is overlapped with the base portion in a planar view.

According to this application example, since the vibration displacement amount of the base portion is small compared to the vibration portion, it is possible to obtain a vibrator having a small amount of vibration leakage.

### Application Example 6

This application example is directed to the vibrator according to the application example described above, wherein the supporting portion is polygonal in a planar view.

According to this application example, by providing many corners in which stress generated by the vibration of the polygon is concentrated, the stress can be suppressed. For this reason, it is possible to obtain a vibrator having a stable vibration characteristic.

### Application Example 7

This application example is directed to the vibrator according to the application example described above, wherein the supporting portion is rectangular in a planar view.

According to this application example, since the substantially rectangular base portion can be efficiently supported, it is possible to obtain a vibrator having excellent impact resistance.

### Application Example 8

This application example is directed to the vibrator according to the application example, the supporting portion has a curved portion in a planar view.

According to this application example, as the supporting portion has the curved portion and the corner in which the stress generated by the concentrated vibration is eliminated, the stress can be further suppressed. For this reason, it is possible to obtain a vibrator having a more stable vibration characteristic.

### Application Example 9

This application example is directed to the vibrator according to the application example described above, wherein in a planar view, the supporting portion extends toward a part where the adjacent vibration portions are connected to each other.

According to this application example, since a direction toward the part where the vibration portions are connected to each other from a center part of the base portion substantially matches the vibration node, it is possible to support the part where the vibration displacement amount is small, and to obtain a vibrator having higher vibration efficiency and suppressed vibration leakage.

### Application Example 10

This application example is directed to the vibrator according to the application example described above, wherein in a planar view, a width of the supporting portion is reduced toward the part where the adjacent vibration portions are connected to each other.

According to this application example, as the width of the supporting portion is reduced toward the part where the adjacent vibration portions are connected to each other, it is possible to more accurately support an area where the vibration displacement amount is small, and to obtain a vibrator having higher vibration efficiency and suppressed vibration leakage.

### Application Example 11

This application example is directed to the vibrator according to the application example described above, wherein the supporting portion is disposed along the vibration node in a planar view.

According to this application example, since the supporting portion is provided along the vibration node, it is possible to support a part which has an extremely small vibration displacement amount, and to obtain a vibrator having higher vibration efficiency and suppressed vibration leakage.

### Application Example 12

This application example is directed to the vibrator according to the application example described above, wherein a plurality of the supporting portions are provided.

According to this application example, compared to a case where one supporting portion is provided at the center part of the base portion, it is possible to improve the impact resistance, and to obtain a vibrator having excellent impact resistance and a high Q value in which vibration leakage is suppressed.

### Application Example 13

This application example is directed to an oscillator including the vibrator according to the application example described above.

According to this application example, as the vibrator having a high Q value is provided, it is possible to provide an oscillator having higher functionality.

### Application Example 14

This application example is directed to an electronic device including the vibrator according to the application example described above.

According to this application example, as the vibrator having a high Q value is used as the electronic device, it is possible to provide an electronic device having higher functionality.

### Application Example 15

This application example is directed to a moving object including the vibrator according to application example described above.

According to this application example, as the vibrator having a high Q value is used as the moving object, it is possible to provide a moving object having higher functionality.

### BRIEF DESCRIPTION OF THE DRAWINGS

The invention will be described with reference to the accompanying drawings, wherein like numbers reference like elements.

FIGS. 1A to 1C are plan views and cross-sectional views of a vibrator according to an embodiment of the invention.

FIGS. 2A and 2B are analysis results of vibration displacement of the vibrator according to the embodiment. FIG. 2A is a plan view illustrating the vibration displacement. FIG. 2B is a perspective view illustrating the vibration displacement.

FIGS. 3A to 3D are plan views illustrating an example of a variation of a supporting portion provided on an upper electrode in a vibrator according to Modification Example 1.

FIGS. 4E to 4H are plan views illustrating an example of a variation of the supporting portion provided on the upper electrode in the vibrator according to Modification Example 1.

FIGS. 5A to 5D are plan views illustrating an example of a variation of an upper electrode in a vibrator according to Modification Example 2.

FIGS. 6A to 6F are flow charts illustrating a manufacturing process of the vibrator in order according to the embodiment.

FIGS. 7G to 7K are flow charts illustrating the manufacturing process of the vibrator in order according to the embodiment.

FIG. 8 is a schematic view illustrating a configuration example of an oscillator provided with the vibrator according to the embodiment.

FIG. 9A is a perspective view illustrating a configuration of a mobile type personal computer as an example of an electronic device. FIG. 9B is a perspective view illustrating a configuration of a mobile phone as an example of the electronic device.

FIG. 10 is a perspective view illustrating a configuration of a digital still camera as an example of the electronic device.

FIG. 11 is a schematic perspective view illustrating a vehicle as an example of a moving object.

### DESCRIPTION OF EXEMPLARY EMBODIMENTS

Hereinafter, an embodiment which implements the invention will be described with reference to the drawings. Hereinafter, an embodiment of the invention is described, and the invention is not limited thereto. In addition, in each drawing below, there is a case where the dimensions are different from the real dimensions for easier understanding.

### EMBODIMENT

### Vibrator

First, a MEMS vibrator 100 will be described as a vibrator according to an embodiment of the invention.

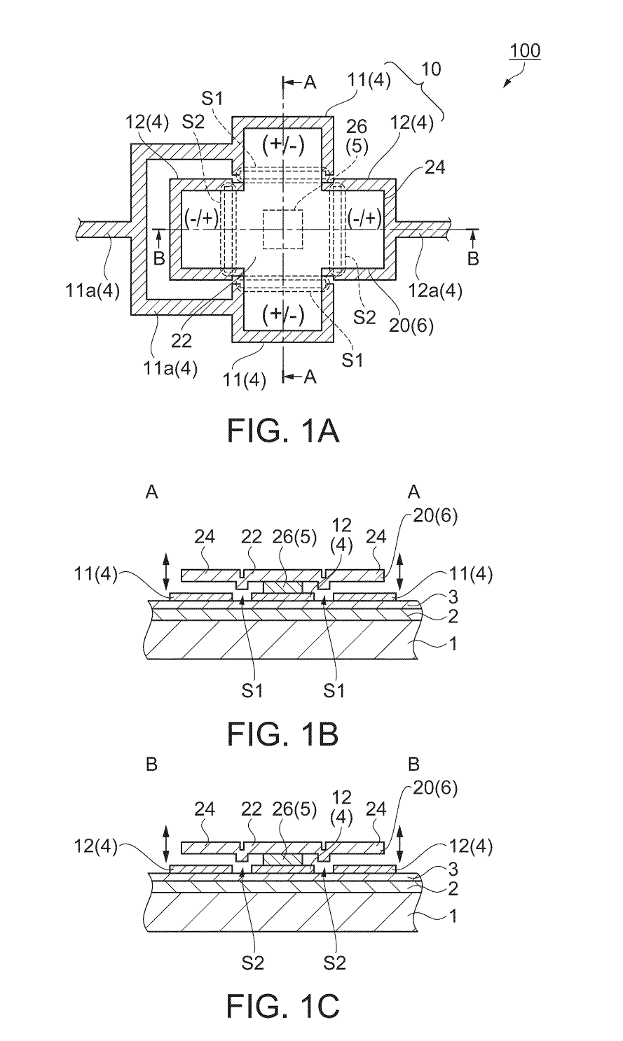

FIG. 1A is a plan view of the MEMS vibrator 100. FIG. 1B is a cross-sectional view along line A-A in FIG. 1A. FIG. 1C is a cross-sectional view along line B-B in FIG. 1A.

The MEMS vibrator 100 is an electrostatic beam type vibrator which is provided with a fixed electrode (lower electrode 10) formed on a substrate 1 and a movable electrode (upper electrode 20) formed to be separated from the substrate 1 and the fixed electrode. The movable electrode is formed to be separated from the substrate 1 and the fixed electrode as a sacrificing layer stacked on a main surface of the substrate 1 and the fixed electrode is etched thereon.

In addition, the sacrificing layer is a layer formed once by an oxide film or the like, and is removed by etching after forming a necessary layer above and below or in the vicinity thereof. As the sacrificing layer is removed, a necessary gap or a cavity is formed between each layer above and below or in the vicinity thereof, and a necessary structure is formed to be separated.

A configuration of the MEMS vibrator 100 will be described hereinafter. A manufacturing method of the MEMS vibrator 100 will be described in the embodiment which will be described below.

The MEMS vibrator 100 is configured to have the substrate 1, the lower electrode 10 (first lower electrode 11, second lower electrode 12) provided on the main surface of the substrate 1, a supporting portion 26 which is connected to the substrate 1 via the lower electrode 10 (second lower electrode 12), an upper electrode 20 (integrated with the base portion 22 and a vibration portion 24) provided with a base portion 22 which is connected to the supporting portion 26, and the like.

As the substrate 1, a silicon substrate is used as a suitable example. On the substrate 1, an oxide film 2 and a nitride film 3 are stacked in order. In an upper portion of the main surface side (surface of the nitride film 3) of the substrate 1, the lower electrode 10 (first lower electrode 11, second lower electrode 12), the supporting portion 26, the upper electrode 20, and the like, are formed.

In addition, here, in a thickness direction of the substrate 1, a direction in which the oxide film 2 and the nitride film 3 are stacked in order on the main surface of the substrate 1 is described as an upward direction.

In the lower electrode 10, the second lower electrode 12 is a fixed electrode which fixes the supporting portion 26 onto the substrate 1, imparts an electric potential to the upper electrode 20 via the supporting portion 26, and is formed as illustrated in FIG. 1A by patterning a first conductor layer 4 stacked on the nitride film 3 by photolithography (including etching processing. The same hereinafter). In addition, the second lower electrode 12 is connected with an outer circuit (not illustrated) by wiring 12a.

The supporting portion 26 is rectangular in a planar view, is overlapped with the base portion 22 of the upper electrode 20, and is disposed to have a part which is overlapped with the vibration node in the base portion 22. Furthermore, the supporting portion 26 is disposed at a center part of the second lower electrode 12. The supporting portion 26 is formed by patterning a second conductor layer 5 which is stacked on the first conductor layer 4 by photolithography. In addition, the first conductor layer 4 and the second conductor layer 5 use conductive polysilicon as a suitable example, respectively, but, the embodiment is not limited thereto.

The upper electrode 20 is configured to have the base portion 22 and a plurality of vibration portions 24 which extends in a direction different from each other from the base portion 22. In particular, as illustrated in FIG. 1A, the upper electrode 20 is a movable electrode which forms a cross shape with the four vibration portions 24 that extend from the base portion 22 of the upper electrode 20, is supported by the supporting portion 26 provided under the base portion 22, and is separated from the substrate 1.

The upper electrode 20 is formed by patterning a third conductor layer 6 which is stacked on an upper layer of the second conductor layer 5 that forms the supporting portion 26 and an upper layer of the sacrificing layer stacked on the first conductor layer 4, by photolithography. In other words, the upper electrode 20 is integrally formed with the base portion 22 and the four vibration portions 24. In addition, center parts of the second lower electrode 12 and the cross-shaped upper electrode 20 are overlapped to be substantially matched with each other when the substrate 1 is viewed from a planar view, and the two vibration portions 24 which extend in a lateral direction (B-B direction) from the base portion 22 of the upper electrode 20 are disposed to be overlapped with the second lower electrode 12 (remove a part of a slit S2 which will be described later). In addition, the third conductor layer 6 uses conductive polysilicon as a suitable example, similarly to the first conductor layer 4 and the second conductor layer 5, but the embodiment is not limited thereto.

In the lower electrode 10, the first lower electrode 11 is a fixed electrode to which an AC voltage is applied between the first lower electrode 11 and the upper electrodes 20 overlapped when the substrate 1 is viewed from a planar view, and is formed by patterning the first conductor layer 4 stacked on the nitride film 3 by photolithography. When FIG. 1A is viewed from a front view, the first lower electrode 11 is provided at two locations to be overlapped with the two vibration portions 24 which extend in a longitudinal direction (A-A direction) from the base portion 22 of the upper electrode 20, and are connected with the outer circuit (not illustrated) by wiring 11a.

The first lower electrode 11 is formed by the first conductor layer 4 which is the same layer as the second lower electrode 12. Therefore, the first lower electrode 11 is required to be electrically insulated between the first lower electrode 11 and the second lower electrode 12 as the fixed electrode which imparts the electric potential to the upper electrode 20, and each pattern (first lower electrode 11, second lower electrode 12) is separated. A step difference (unevenness) of a gap for the separation is transferred to the upper electrode 20 which is formed by the third conductor layer 6 stacked via the sacrificing layer stacked on the upper layer of the first conductor layer 4, in an uneven shape. In particular, as illustrated in FIGS. 1A and 1B, in a part of a separation portion (slit S1) of the pattern, the uneven shape is formed in the upper electrode 20.

In the MEMS vibrator 100, in order to prevent an occurrence of a difference in stiffness by the vibration portion 24 which extends in the longitudinal direction (A-A direction) from the base portion 22 of the upper electrode 20 and the vibration portion 24 which extends in the lateral direction (B-B direction), a dummy slit pattern is provided in the second lower electrode 12. In particular, like the uneven shape reflected to the two vibration portions 24 in which the slit S1 extends in the longitudinal direction (A-A direction) of the upper electrode 20, a dummy slit S2 which generates the uneven shape in the two vibration portions 24 in which the slit S1 extends in the lateral direction (B-B direction) of the upper electrode 20, is provided in the second lower electrode 12 in which the slit S1 extends in the lateral direction (B-B direction) in an area where the upper electrode 20 is overlapped. In other words, a width of the slit S2 is substantially the same as a width of the slit S1. The slit S2 is formed so that a distance from a position where a center point of the upper electrode 20 is overlapped to the slit S2 is substantially the same as the distance from the position where the center point of the upper electrode 20 is overlapped to the slit S1, in a planar view.

As the dummy slit S2 is provided in this manner, the upper electrode 20 is configured to include an uneven portion. In addition, since the slit S2 is not formed for electrically insulating the second lower electrode 12, in a planar view, in the area where both end portions of the slit S2 which is not overlapped with the upper electrode 20, the second lower electrode 12 continues.

In the configuration, the MEMS vibrator 100 is configured as an electrostatic vibrator. By the AC voltage applied between the first lower electrode 11 and the upper electrode 20 via the wirings 11a and 12a from the outer circuit, a tip end area of the four vibration portions 24 of the upper electrode 20 vibrates as an antinode of the vibration. In FIG. 1A, a (+/−) signal illustrates a part which vibrates in a vertical direction (thickness direction of the substrate 1) as the antinode of the vibration, including a phase relationship of the vibration. In addition, the phases of the adjacent vibration portions 24 are different from each other. For example, the signal illustrates a case where the + vibration portion 24 moves in the upward direction (direction away from the substrate 1) and the adjacent vibration portion 24 moves in the downward direction (direction which approaches the substrate 1). In other words, the upper electrode 20 which is the movable electrode vibrates in a direction which intersects a plane surface including the lower electrode 10 (first lower electrode 11, second lower electrode 12) which is the fixed electrode.

Here, the two vibration portions 24 which pinch the base portion 22 in a direction different from the base portion 22, are regarded as a beam in a substantially rectangular shape including the base portion 22. For this reason, flexural vibration is generated which has displacement in the thickness direction of the vibration portion 24 in which the base portion 22 vibrates in the downward direction when the tip ends of the two vibration portions 24 vibrate in the upward direction. In addition, the adjacent vibration portions 24, the base portion 22, and the beam which is configured by the two vibration portions 24 which pinch the base portion 22 and extend in different directions from the base portion 22, generate flexural vibration, in which the base portion 22 vibrates in the upward direction when the tip ends of the two vibration portions 24 vibrate in the downward direction. For this reason, when the two beams vibrate at the same time, the displacement of the base portion 22 in a vertical direction is offset and vibration is suppressed, and the area in which the base portion 22 and the vibration portion 24 are connected to each other becomes the vibration node. Accordingly, the vibration of the entire upper electrode 20 in the vibration node is balanced. By supporting this part, it is possible to more simply provide an electrostatic beam type vibrator having higher vibration efficiency and suppressed vibration leakage.

Next, the vibration node of the vibrator according to the embodiment will be described in detail.

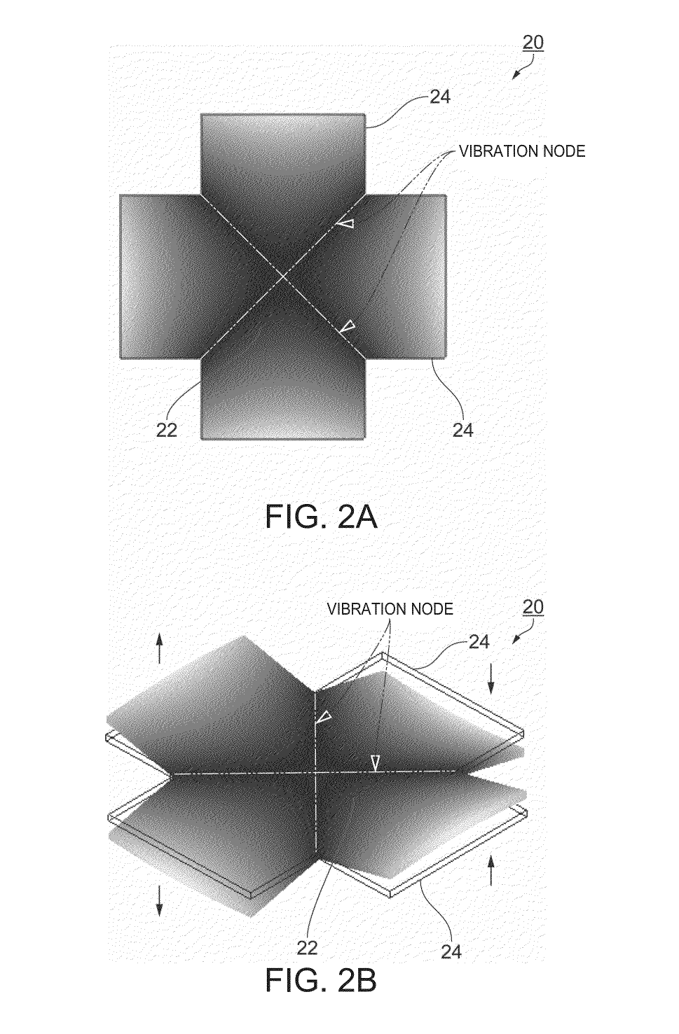

FIGS. 2A and 2B are analysis results of the vibration displacement of the vibrator according to the embodiment. FIG. 2A is a plan view illustrating the vibration displacement. FIG. 2B is a perspective view illustrating the vibration displacement.

FIGS. 2A and 2B illustrate results of calculation of the vibration displacement by a finite element method in a state where the supporting portion is provided on the substrate 1 side of the base portion 22 and the base portion 22 of the supporting portion and an opposite side are fixed to each other, and illustrates the vibration displacement is small at a dark black-colored part and the vibration displacement is large at a white-colored, in the upper electrode 20 which is provided with the four vibration portions 24 that extend in a cross shape from the base portion 22, similarly to the vibrator according to the embodiment.

In FIGS. 2A and 2B, the vibration displacement is large at a tip end portion (side opposite to a side which is connected to the base portion 22) of each vibration portion 24 and the vibration displacement is small at the base portion 22. In addition, in a part which is illustrated as a two-dot chain line which links a part where the adjacent vibration portions 24 are connected to each other and a part where the adjacent vibration portions 24 which pinch the center part of the base portion 22 at a facing position are connected to each other, the vibration displacement is extremely small, and rarely exists. For this reason, it is possible to regard the part as the vibration node. In addition, the vibration node is disposed between the center part of the base portion 22 and the parts (four locations) in which the adjacent vibration portions 24 are connected to each other, and has a cross shape.

Accordingly, by supporting the part of the vibration node, in particular, the part of the cross shape, it is possible to more simply provide an electrostatic beam type vibrator having higher vibration efficiency and suppressed vibration leakage.

In addition, the invention is not limited thereto, and various modifications or improvements are possible in the above-described embodiment. Modification examples will be described hereinafter. Here, the same configuration part as the above-described embodiment will use the same reference numerals and the repeated description thereof will be omitted.

### Modification Example 1

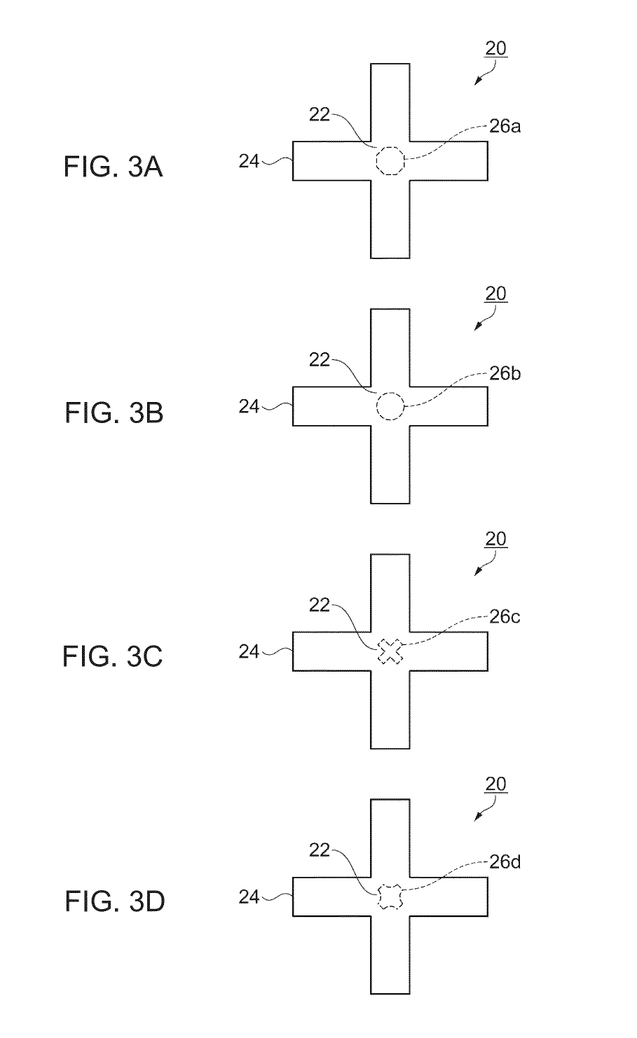

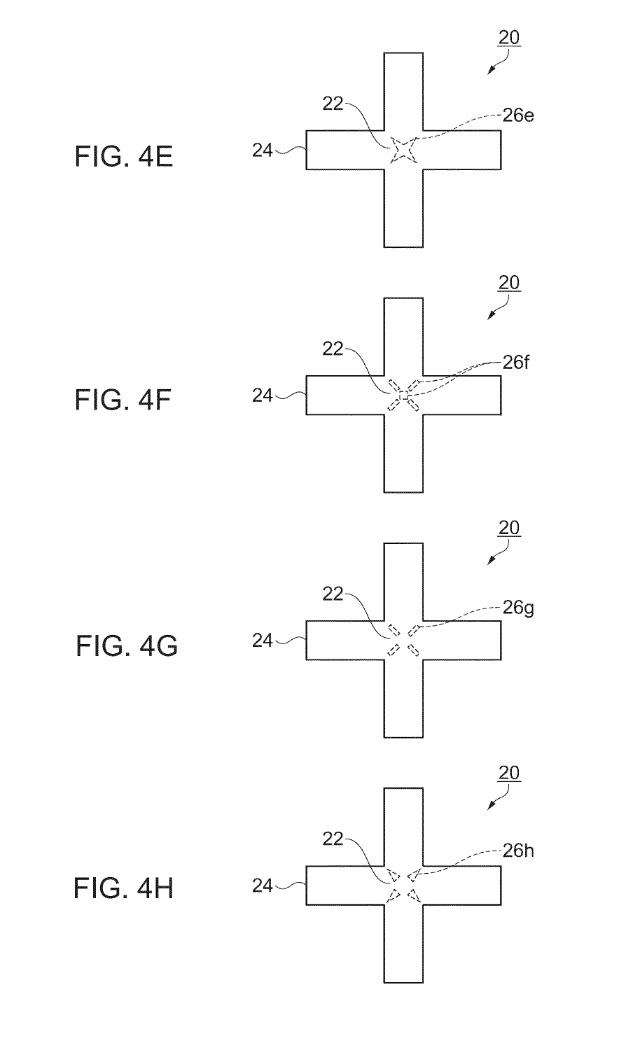

FIGS. 3A to 3D and FIGS. 4E and 4H are plan views illustrating an example of a variation of the supporting portion provided on the upper electrode in a vibrator (MEMS vibrator 100) according to Modification Example 1.

In the embodiment, as illustrated in FIG. 1A, the supporting portion 26 is configured to be rectangular, but the configuration is not limited thereto. In addition, one supporting portion 26 is provided, but the configuration is not limited thereto, and a plurality of supporting portions 26 may be provided.

FIG. 3A is an example illustrating a polygonal shape of a supporting portion 26a. As the supporting portion 26a is polygonal, since there are many corners of the supporting portion 26a compared to a rectangular shape, it is possible to suppress the concentration of the stress generated by vibration. For this reason, it is possible to obtain a MEMS vibrator 100 having a stable vibration characteristic.

FIG. 3B is an example illustrating a shape of a supporting portion 26b having a curved portion. As the supporting portion 26b has the curved portion, since it is possible to suppress the concentration of the stress generated by vibration, it is possible to obtain a MEMS vibrator 100 having a more stable vibration characteristic.

FIG. 3C is an example illustrating a shape of a supporting portion 26c having four rectangles which extend from the center part of the base portion 22 to a part in which the adjacent vibration portions 24 are connected. Since the supporting portion 26c is provided along the vibration node illustrated in FIGS. 2A and 2B, it is possible to support the part where the vibration displacement is extremely small, and to obtain a MEMS vibrator 100 having higher vibration efficiency and suppressed vibration leakage.

FIG. 3D is an example illustrating a shape of a supporting portion 26d which has rectangles along the vibration node similarly to the supporting portion 26c illustrated in FIG. 3C. In the supporting portion 26d, since a part where the adjacent rectangles are connected to each other is in a curved shape, an area of the supporting portion 26d becomes great in a planar view, and the impact resistance can be improved. It is possible to obtain a MEMS vibrator 100 having excellent impact resistance, higher vibration efficiency, and suppressed vibration leakage.

FIG. 4E is an example illustrating a shape of a supporting portion 26e having rectangles along the vibration node similarly to the supporting portion 26c illustrated in FIG. 3C. In the supporting portion 26e, a width of the rectangle along the vibration node decreases toward the part where the adjacent rectangles are connected to each other in a planar view. In other words, since the width becomes smaller, it is possible to more accurately support the area where the vibration displacement is small, and to obtain a MEMS vibrator 100 having higher vibration efficiency and suppressed vibration leakage.

FIG. 4F is an example illustrating a shape of a supporting portion 26f which has a rectangular supporting portion at the center part of the base portion 22 and a plurality of rectangular supporting portions along the vibration node. In the supporting portion 26f, compared to a case where one supporting portion is provided at the center part of the base portion 22, the impact resistance is improved, and it is possible to obtain a MEMS vibrator 100 having excellent impact resistance and a high Q value in which vibration leakage is suppressed.

FIG. 4G is an example illustrating a shape of a supporting portion 26g which has a plurality of rectangular supporting portions along the vibration node. Since the supporting portion 26g has the plurality of supporting portions provided along the vibration node, it is possible to more accurately support only the area in which the vibration displacement is small, and to obtain a MEMS vibrator 100 having a high Q value in which vibration leakage is suppressed.

FIG. 4H is an example illustrating a shape of a supporting portion 26h in which a width of a plurality of rectangular supporting portions along the vibration node decreases toward an outer edge portion of the base portion 22. Since the width of the supporting portion 26h decreases at the rectangular tip end portion, it is possible to more accurately support only the area in which the vibration displacement is small, and to obtain a MEMS vibrator 100 having a high Q value in which vibration leakage is suppressed.

### Modification Example 2

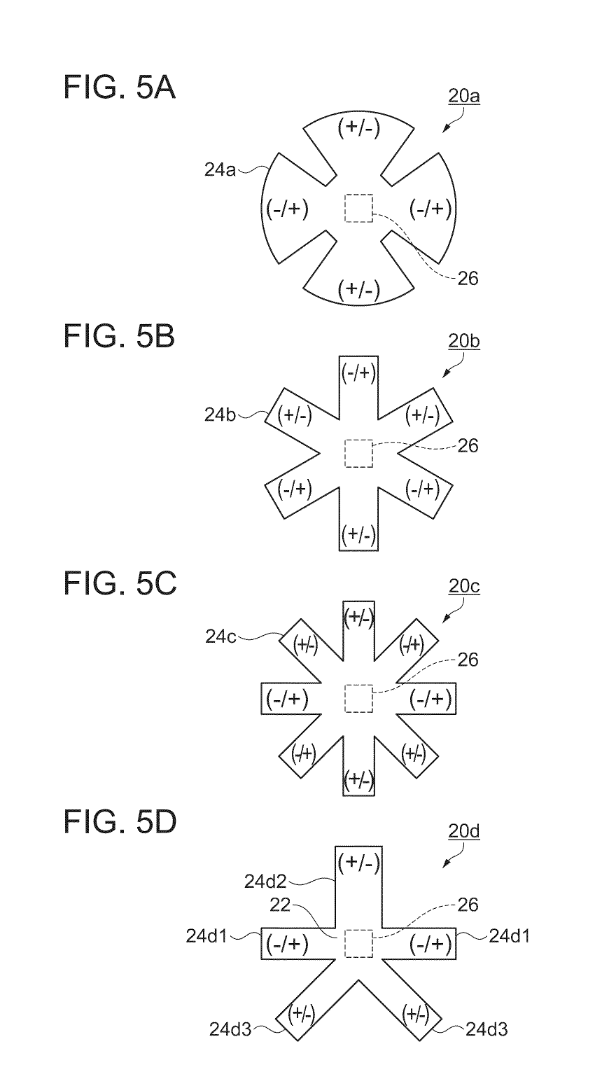

FIGS. 5A to 5D are plan views illustrating an example of a variation of the upper electrode in a vibrator (MEMS vibrator 100) according to Modification Example 2.

In the embodiment, as illustrated in FIG. 1A, the upper electrode 20 is described as the upper electrode 20 which forms a cross shape with the four vibration portions 24 which extend from the base portion 22. However, the configuration is not limited thereto. The number of the vibration portions 24 may be an even number or an odd number, and four or more upper electrodes 20 may be formed.

FIG. 5A is an example illustrating an upper electrode 20a configured in a disc shape. When vibration occurs such that phases of the vibration of vibration portions 24a adjacent to each other are reversed, it is possible to provide a MEMS vibrator 100 having a high Q value in which the deterioration of vibration efficiency and vibration leakage are suppressed.

FIG. 5B is an example illustrating an upper electrode 20b having six vibration portions 24b. When vibration occurs such that phases of the vibration of the vibration portions 24b adjacent to each other are reversed, it is possible to provide a MEMS vibrator 100 having a high Q value in which the deterioration of vibration efficiency and vibration leakage are suppressed.

FIG. 5C is an example illustrating an upper electrode 20c having eight vibration portions 24c. When the vibration occurs such that phases of the vibration of the vibration portions 24c adjacent to each other are reversed, or when two vibration portions 24c adjacent to each other vibrate as one group in the same phase as illustrated in FIG. 5C, and the vibration occurs such that the phases of the vibration of the adjacent groups are reversed, it is possible to provide a MEMS vibrator 100 having a high Q value in which the deterioration of vibration efficiency and vibration leakage are suppressed.

FIG. 5D is an example illustrating an upper electrode 20d having five vibration portions 24d1 to 24d3. A vibration portion 24d2 and two vibration portions 24d3 which pinch the base portion 22 at a facing position have different lengths (length in a width direction) of a direction which intersects with a direction that extends from the base portion 22, and the length of a width direction of the vibration portion 24d2 is relatively longer than the length of a width direction of the two vibration portions 24d3. This is done to balance the vibration of the entire upper electrode 20d in which the base portion 22 and the vibration portions 24d1, 24d2, and 24d3 are integrated in a vibration node. By this configuration, even when the total number of the vibration portions 24d1, 24d2, and 24d3 is an odd number, it is possible to provide a MEMS vibrator 100 having a high Q value in which the deterioration of vibration efficiency and vibration leakage are suppressed.

### Manufacturing Method

Next, a manufacturing method of the vibrator (MEMS vibrator 100) according to the embodiment will be described. In addition, according to the description, the same configuration location described above will use the same reference numerals and the repeated description thereof will be omitted.

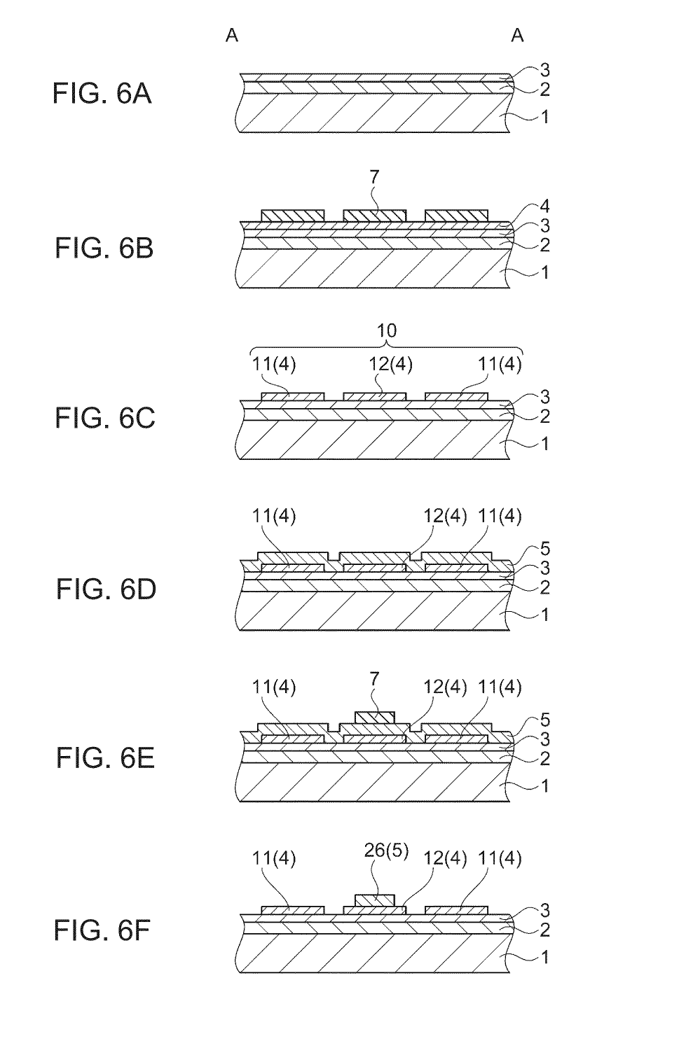

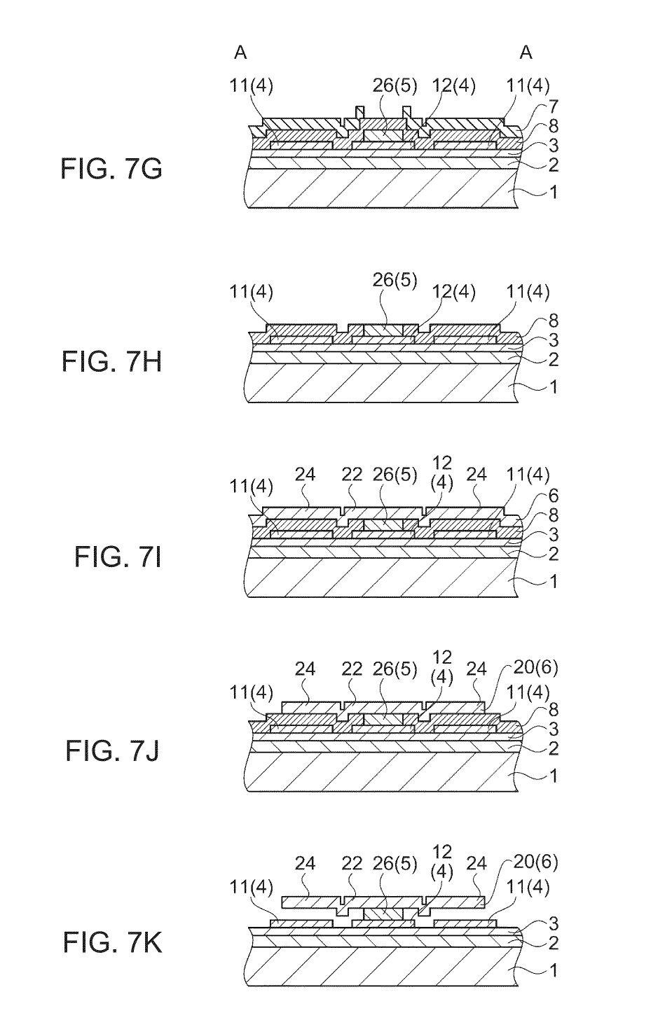

FIGS. 6A to 6F and FIGS. 7G to 7K are flow charts illustrating the manufacturing process of the MEMS vibrator 100 in order. States of the MEMS vibrator 100 in each process will be illustrated in the cross-sectional view taken along line A-A in FIG. 1A.

FIG. 6A: The substrate 1 is prepared and the oxide film 2 is stacked on the main surface. The oxide film 2 is formed by a general local oxidation of silicon (LOCOS) as an element separation layer in a semiconductor process as a suitable example, but may be an oxide film according to generation of the semiconductor process, for example, according to a shallow trench isolation (STI) method.

Next, the nitride film 3 is stacked as an insulating layer. Silicon nitride (Si₃N₄) forms the nitride film 3 by a low pressure chemical vapor deposition (LPCVD). The nitride film 3 has a resistance with respect to buffered hydrogen fluoride as an etchant which is used at a time of release etching of a sacrificing layer 8 (refer to FIG. 7G) which will be described later, and functions as an etching stopper.

FIGS. 6B and 6C: Then, as a first layer forming process, first of all, the first conductor layer 4 is stacked on the nitride film 3. The first conductor layer 4 is a polysilicon layer which is configured to have the lower electrode 10 (first lower electrode 11, second lower electrode 12), the wirings 11a and 12a (refer to FIG. 1A), or the like, and has a predetermined conductivity by injecting ions, such as boron (B) or phosphorus (P) after the stacking. Next, by coating a resist 7 on the first conductor layer 4 and patterning by photolithography, the first lower electrode 11, the second lower electrode 12, and the wirings 11a and 12a are formed. In the first layer forming process, when the substrate 1 is viewed from a planar view after a third layer forming process, the lower electrode 10 is formed in advance to be overlapped with the upper electrode 20, in other words, the first lower electrode 11 and the second lower electrode 12 are formed.

FIG. 6D: Next, as a second layer forming process, the second conductor layer 5 is stacked to cover the lower electrode 10 and the wirings 11a and 12a. The second conductor layer 5 is a polysilicon layer which constitutes the supporting portion 26, and has the predetermined conductivity by injecting ions, such as boron (B) or phosphorus (P) after the stacking.

FIGS. 6E and 6F: Next, the resist 7 is coated on the second conductor layer 5, and by patterning by photolithography, the supporting portion 26 is formed. The supporting portion 26 forms a gap in the first lower electrode 11, the second lower electrode 12, and the upper electrode 20, separates the upper electrode 20, and is formed to be overlapped in the center part of the second lower electrode 12.

FIGS. 7G and 7H: Next, a sacrificing layer 8 is stacked to cover the lower electrode 10, the wirings 11a and 12a, and the supporting portion 26. The sacrificing layer 8 forms the gap between the first lower electrode 11 and the second lower electrode 12, and the upper electrode 20, is a sacrificing layer for separating the upper electrode 20, and forms a film using the chemical vapor deposition (CVD) method. On the stacked sacrificing layer 8, an unevenness caused by a step difference of the patterned first lower electrode 11 or second lower electrode 12 appears. Then, the resist 7 is coated on the sacrificing layer 8, and the sacrificing layer 8 on the supporting portion 26 is removed after the patterning by photolithography.

FIGS. 7I and 7J: Next, as the third layer forming process, first of all, the third conductor layer 6 is stacked to cover the sacrificing layer 8 and the supporting portion 26. The third conductor layer 6 is a polysilicon layer which is the same as the first conductor layer 4 or the second conductor layer 5, and has the predetermined conductivity by injecting ions, such as boron (B) or phosphorus (P) after the stacking. After that, by patterning by photolithography, the upper electrode 20 (base portion 22 and vibration portion 24) is formed. As illustrated in FIG. 1A, as an electrode which has an area that overlaps the first lower electrode 11 and the second lower electrode 12 when the substrate 1 is viewed from a planar view, the upper electrode 20 is formed in a shape such that the vibration portions 24 extend in a radial shape from the base portion 22 of the center of the upper electrode 20.

FIG. 7K: Next, by bleaching the substrate 1 by the etchant (buffered hydrogen fluoride) and etching-removing (release etching) the sacrificing layer 8, the gap between the first lower electrode 11 and the second lower electrode 12, and the upper electrode 20 is formed, and the upper electrode 20 is separated.

According to the description above, the MEMS vibrator 100 is formed.

In addition, it is preferable that the MEMS vibrator 100 be disposed in a cavity portion which is sealed in a decompression state. For this reason, in manufacturing the MEMS vibrator 100, the sacrificing layer for forming the cavity portion, a side wall portion which surrounds the sacrificing layer, a sealing layer which forms a lid of the cavity portion, or the like, are formed to be combined, but the description thereof is omitted here.

As described above, according to the MEMS vibrator 100 in the embodiment, it is possible to obtain the following effects.

In the upper electrode 20, since the vibration node of the base portion 22 is supported by the supporting portion 26, the vibration of the entire upper electrode 20 is balanced by the vibration node, and it is possible to provide an electrostatic beam type vibrator which has higher vibration efficiency and a high Q value in which vibration leakage is suppressed.

### Oscillator

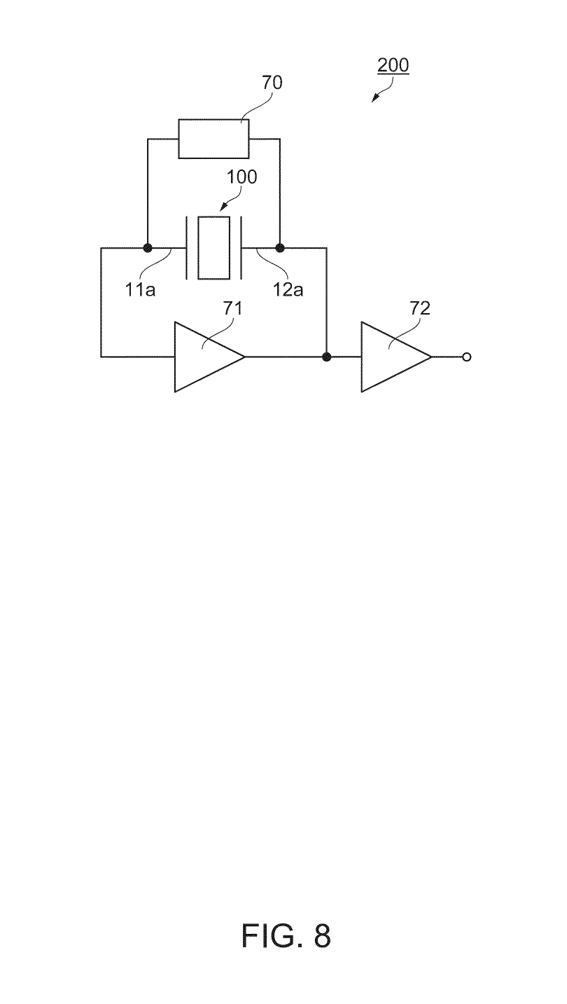

Next, an oscillator 200 which employs the MEMS vibrator 100 as an oscillator according to an embodiment of the invention will be described based on FIG. 8.

FIG. 8 is a schematic view illustrating a configuration example of an oscillator provided with the MEMS vibrator 100 according to an embodiment of the invention. The oscillator 200 is configured to have the MEMS vibrator 100, a bias circuit 70, amplifiers 71 and 72, or the like.

The bias circuit 70 is a circuit which is connected to the wirings 11a and 12a of the MEMS vibrator 100, and applies the AC voltage in which a predetermined electric potential is biased in the MEMS vibrator 100.

The amplifier 71 is a feedback amplifier which is connected to the wirings 11a and 12a of the MEMS vibrator 100, in parallel with the bias circuit 70. By performing the feedback amplification, the MEMS vibrator 100 is configured as the oscillator 200.

The amplifier 72 is a buffer amplifier which outputs an oscillation waveform.

According to the embodiment, as the MEMS vibrator 100 having a high Q value is provided as the oscillator 200, it is possible to provide an oscillator 200 having higher functionality.

### Electronic Device

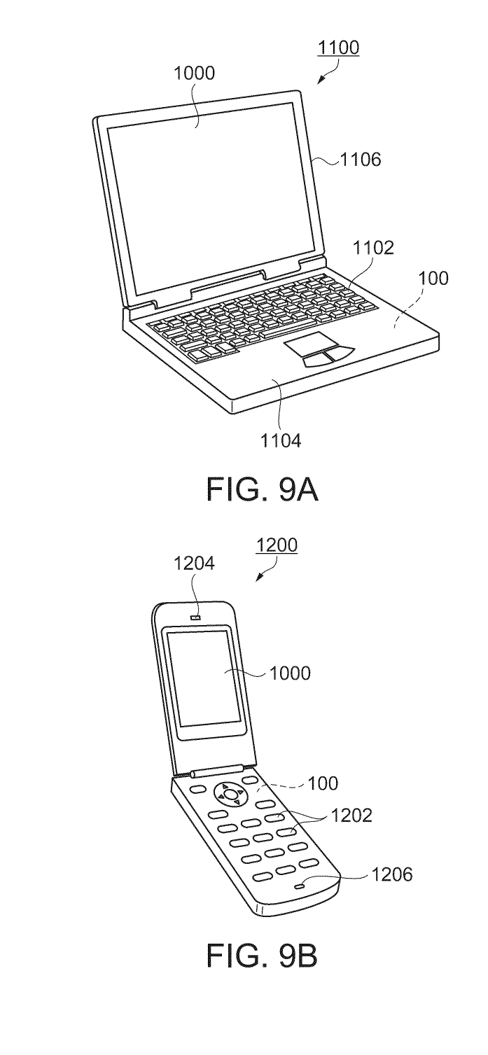

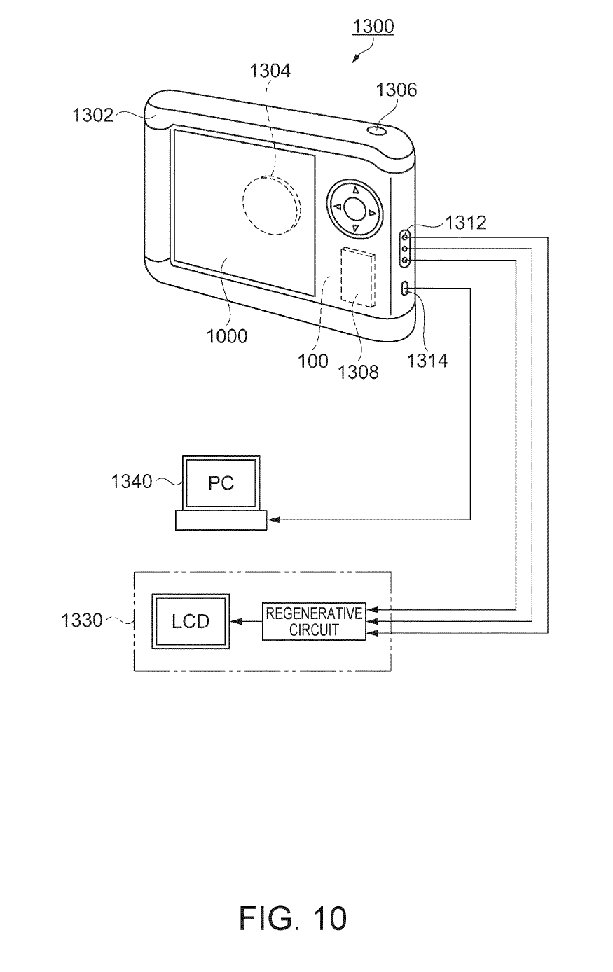

Next, an electronic device which employs the MEMS vibrator 100 as an electronic component according to an embodiment of the invention will be described based on FIGS. 9A and 9B, and 10.

FIG. 9A is a schematic perspective view illustrating a configuration of a mobile-type (or note-type) personal computer as the electronic device provided with the electronic component according to the embodiment of the invention. In the drawing, a personal computer 1100 is configured to have a main body portion 1104 provided with a keyboard 1102 and a display unit 1106 provided with a display portion 1000. The display unit 1106 is supported to be rotatable via a hinge structure portion with respect to the main body portion 1104. In the personal computer 1100, the MEMS vibrator 100 as the electronic component which functions as a filter, a resonator, a reference clock, or the like is embedded.

FIG. 9B is a schematic perspective view illustrating a configuration of a mobile phone (including PHS) as the electronic device provided with the electronic component according to the embodiment of the invention. In the drawing, a mobile phone 1200 is provided with a plurality of operation buttons 1202, an ear piece 1204, and a mouth piece 1206. The display portion 1000 is disposed between the operation button 1202 and the ear piece 1204. In the mobile phone 1200, the MEMS vibrator 100 as the electronic component (timing device) which functions as the filter, the resonator, an angular velocity sensor, or the like is embedded.

FIG. 10 is a schematic perspective view illustrating a configuration of a digital still camera as the electronic device provided with the electronic component according to the embodiment of the invention. In addition, in the drawing, a connection with an outer device is also simply illustrated. A digital still camera 1300 performs photoelectric conversion of an optical image of a subject by a photographing element, such as a charged coupled device (CCD), and generates a photographing signal (image signal).

On a rear surface of a case (body) 1302 in the digital still camera 1300, the display portion 1000 is provided, and a display is performed based on the photographing signal by the CCD. The display portion 1000 functions as a finder which displays the subject as an electronic image. In addition, on a front surface side (back surface side in the drawing) of the case 1302, a light receiving unit 1304 including an optical lens (photographing optical system) or the CCD is provided.

When a photographer confirms a subject image displayed on the display portion 1000 and pushes a shutter button 1306, the photographing signal of the CCD at that moment is sent and stored in a memory 1308. In addition, in the digital still camera 1300, on a side surface of the case 1302, a video signal output terminal 1312 and a data communication input and output terminal 1314 are provided. As illustrated in the drawing, a television monitor 1330 is connected to the video signal output terminal 1312, and a personal computer 1340 is connected to the data communication input and output terminal 1314, as necessary, respectively. Furthermore, according to a predetermined operation, the photographing signal stored in the memory 1308 is output to the television monitor 1330 or the personal computer 1340. In the digital still camera 1300, the MEMS vibrator 100 as the electronic component which functions as the filter, the resonator, the angular velocity sensor, or the like is embedded.

As described above, as the vibrator (MEMS vibrator 100) having a high Q value is used as the electronic component, it is possible to provide an electronic device having higher functionality.

In addition, the MEMS vibrator 100 as the electronic component according to the embodiment of the invention can be employed in the electronic device, such as an ink jet type discharging apparatus (for example, an ink jet printer), a laptop type personal computer, a television, a video camera, a car navigation apparatus, a pager, an electronic organizer (including an electronic organizer having a communication function), an electronic dictionary, an electronic calculator, an electronic game device, a work station, a video telephone, a television monitor for crime prevention, a pair of electronic binoculars, a POS terminal, a medical device (for example, an electronic thermometer, a sphygmomanometer, a blood sugar meter, an electrocardiograph, an ultrasonic diagnostic equipment, and an electronic endoscope), a fish finder, various measurement apparatuses, meters (for example, meters of the vehicle, an aircraft, or a vessel) or a flight simulator, in addition to the personal computer (mobile type personal computer) in FIG. 9A, the mobile phone in FIG. 9B, and the digital still camera in FIG. 10.

### Moving Object

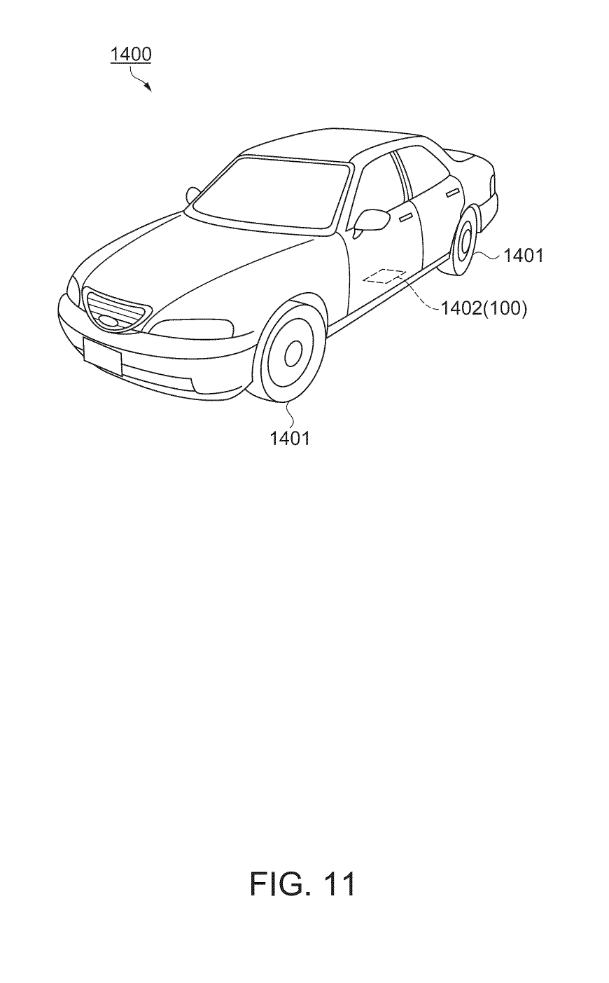

Next, a moving object which employs the MEMS vibrator 100 as the vibrator according to the embodiment of the invention will be described based on FIG. 11.

FIG. 11 is a schematic perspective view illustrating a vehicle 1400 as the moving object provided with the MEMS vibrator 100. In the vehicle 1400, a gyro sensor configured to have the MEMS vibrator 100 according to the embodiment of the invention is mounted. For example, as illustrated in FIG. 11, in the vehicle 1400 as the moving object, an electronic control unit 1402, in which the gyro sensor that controls a tire 1401 is embedded, is mounted. In addition, as another example, the MEMS vibrator 100 can be employed widely in an electronic control unit (ECU), such as a keyless entry, an immobilizer, a car navigation system, a car air conditioner, an anti-lock brake system (ABS), an air bag, a tire pressure monitoring system (TPMS), an engine control, a battery monitor of a hybrid vehicle or an electric vehicle, or a vehicle posture control system.

As described above, as the vibrator (MEMS vibrator 100) having a high Q value is used as the moving object, it is possible to provide a moving object having higher functionality.

As described above, the vibrator (MEMS vibrator 100), the oscillator 200, the electronic device, and the moving object according to the invention are described based on the embodiments illustrated in the drawings. However, the invention is not limited thereto, and the configuration of each part can be replaced with an arbitrary configuration having similar functions. In addition, in the invention, another arbitrary component may be added. In addition, each of the above-described embodiments may be suitably combined.

The entire disclosure of Japanese Patent Application No. 2013-214420, filed Oct. 15, 2013 is expressly incorporated by reference herein.

What is claimed is:

1. A vibrator, comprising:
a substrate;
a supporting portion which is disposed above the substrate;
a base portion which is disposed above the supporting portion and has a vibration node; and
a vibration portion which extends from the base portion,
wherein, in a planar view, at least a part of the supporting portion is overlapped with the vibration node.

2. The vibrator according to claim 1, further comprising:
a fixed electrode, which faces the vibration portion and is disposed above the substrate.

3. The vibrator according to claim 1, further comprising:
a movable electrode having the vibration portion.

4. The vibrator according to claim 2,
wherein the vibration portion vibrates in a direction that intersects a plane surface which includes the fixed electrode.

5. The vibrator according to claim 1,
wherein at least a part of the supporting portion is overlapped with the base portion in a planar view.

6. The vibrator according to claim 1,
wherein the supporting portion is polygonal in a planar view.

7. The vibrator according to claim 1,
wherein the supporting portion is rectangular in a planar view.

8. The vibrator according to claim 1,
wherein the supporting portion has a curved portion in a planar view.

9. The vibrator according to claim 1,
wherein, in a planar view, the supporting portion extends toward a part where the adjacent vibration portions are connected to each other.

10. The vibrator according to claim 9,
wherein, in a planar view, a width of the supporting portion is reduced toward the part where the adjacent vibration portions are connected to each other.

11. The vibrator according to claim 1,
wherein the supporting portion is disposed along the vibration node in a planar view.

12. The vibrator according to claim 1,
wherein there are plural supporting portions.

13. An oscillator, comprising:
the vibrator according to claim 1.

14. An electronic device, comprising:
the vibrator according to claim 1.

15. A moving object, comprising:
the vibrator according to claim 1.
